(19) United States
(12) Patent Application Publication
(10) Pub. No.: US 2014/0220481 A1
(43) Pub. Date: Aug. 7, 2014

(54) PHOTOMASKS AND METHODS OF FABRICATING SEMICONDUCTOR DEVICES USING THE SAME

(71) Applicant: Samsung Electronics Co., Ltd., Suwon-si (KR)

(72) Inventors: Mun Ja Kim, Hwasung-si (KR); Donggun Lee, Hwasung-si (KR); Seongsue Kim, Hwasung-si (KR)

(73) Assignee: Samsung Electronics Co., Ltd., Suwon-si (KR)

(21) Appl. No.: 14/136,560

(22) Filed: Dec. 20, 2013

(30) Foreign Application Priority Data
Feb. 1, 2013 (KR) 10-2013-0011936

(51) Int. Cl. G03F 1/48

(52) U.S. Cl. CPC G03F 1/48
USPC 430/5

(57) ABSTRACT

The present inventive concept provides a photomask including a substrate, patterns disposed on the substrate, and an anti-contamination layer disposed on the patterns. The anti-contamination layer includes at least one graphene layer. Methods of fabricating a semiconductor device including the same are also provided.

### CROSS-REFERENCE TO RELATED APPLICATIONS

This U.S. non-provisional patent application claims priority under 35 U.S.C. §119 to Korean Patent Application No. 10-2013-0011936, filed on Feb. 1, 2013, the entirety of which is incorporated by reference herein.

### BACKGROUND

The inventive concept relates to photomasks and methods of fabricating semiconductor devices using the same and, more particularly, to photomasks capable of minimizing or preventing contamination and methods of fabricating semiconductor devices using the same.

Semiconductor devices are used in the electronic industry at least because of their small size, multi-function and/or low fabrication costs. Semiconductor devices may be formed by various semiconductor processes such as a deposition process, a photolithography process, an ion implantation process, and/or an etching process.

The photolithography process may be a semiconductor process for defining semiconductor patterns in the semiconductor device. The photolithography process generally employs use of a photomask. The photomask includes patterns for defining the semiconductor patterns. The patterns of the photomask may be projected using light on a semiconductor substrate in the photolithography process. Thus, photoresist patterns defining the semiconductor patterns may be formed on the semiconductor substrate.

Meanwhile, if external contamination sources (e.g., fine dust and/or particles) occur on the photomask, shapes of the external contamination sources may be projected onto the semiconductor substrate, possibly causing defects of a semiconductor chip.

### SUMMARY

Embodiments of the inventive concept may provide photomasks capable of minimizing or preventing external contamination.

Embodiments of the inventive concept may also provide methods of fabricating a semiconductor device using the photomasks.

In one aspect, a photomask may include: a substrate; patterns disposed on the substrate; and an anti-contamination layer disposed on the patterns, the anti-contamination layer may include at least one graphene layer and the anti-contamination layer may be disposed directly on the patterns.

In some embodiments, the anti-contamination layer may be in contact with top surfaces of the patterns, but the anti-contamination layer may be spaced apart from the substrate between the patterns.

In some embodiments, the graphene layer of the anti-contamination layer may be in contact with the top surfaces of the patterns.

In some embodiments, the anti-contamination layer may be in contact with surfaces of the patterns and a surface of the substrate between the patterns.

In some embodiments, the anti-contamination layer may further include: a seed layer contacting the surfaces of the patterns and the surface of the substrate between the patterns. In this case, the graphene layer may be disposed on the seed layer and may be in contact with the seed layer.

In some embodiments, the seed layer may include a transition metal.

In some embodiments, the anti-contamination layer may include a plurality of sequentially stacked graphene layers.

In some embodiments, the graphene layer may be doped with impurities.

In some embodiments, the impurities may include at least one of boron, nitrogen, fluorine, platinum, gold, silver, and kalium.

In some embodiments, the substrate may include a material transmitting light generated from a light source; and the patterns may include a material blocking the light.

In some embodiments, the substrate may include a material or structure reflecting light generated from a light source; and the patterns may include a material absorbing the light.

In another aspect, a method of fabricating a semiconductor device may include: forming a photoresist layer on a semiconductor substrate; performing an exposure process on the photoresist layer using a photomask, the photomask including a substrate, patterns on the substrate and an anti-contamination layer disposed directly on the patterns; and performing a developing process on the exposed photoresist layer to form photoresist patterns. The anti-contamination layer may include at least one graphene layer.

In some embodiments, the anti-contamination layer may be in contact with at least top surfaces of the patterns of the photomask.

In some embodiments, the method may further include: removing the graphene layer of the anti-contamination layer using oxygen-plasma when an external contamination material occurs on the anti-contamination layer.

In some embodiments, the method may further include: performing a semiconductor process using the photoresist patterns.

### BRIEF DESCRIPTION OF THE DRAWINGS

The inventive concept will become more apparent in view of the attached drawings and accompanying detailed description.

FIG. 1A is a cross-sectional view illustrating a photomask according to some embodiments of the inventive concept;

FIG. 1B is an enlarged view of a pattern and an anti-contamination layer of FIG. 1A;

FIG. 2 is a graph illustrating a transmittance property of an anti-contamination layer according to embodiments of the inventive concept;

FIG. 3A is a cross-sectional view illustrating a photomask according to other embodiments of the inventive concept;

FIG. 3B is an enlarged view of a pattern and an anti-contamination layer of FIG. 3A;

FIG. 4 is a flowchart illustrating a method of forming a photomask according to some embodiments of the inventive concept;

FIG. 5 is a flowchart illustrating a method of forming a photomask according to other embodiments of the inventive concept;

FIG. 6 is a flowchart illustrating a method of fabricating a semiconductor device according to example embodiments of the inventive concept;

FIGS. 7A to 7D are cross-sectional views illustrating a method of fabricating a semiconductor device according to example embodiments of the inventive concept;

FIG. 8 is schematic diagram illustrating an exposure system to explain an exposure process according to some embodiments of the inventive concept; and

FIG. 9 is schematic diagram illustrating an exposure system to explain an exposure process according to other embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

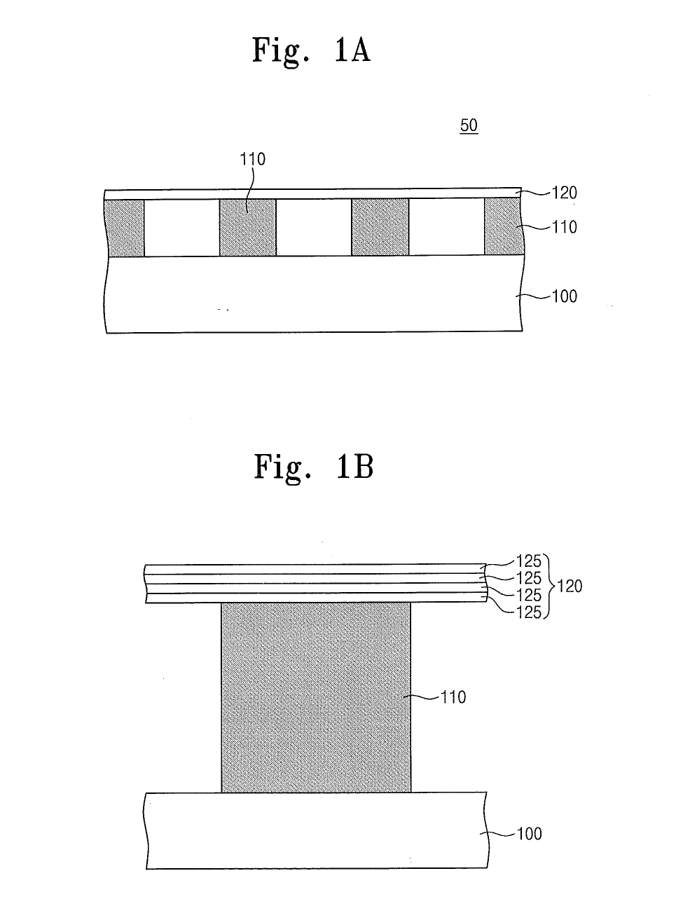

FIG. 1A is a cross-sectional view illustrating a photomask according to some embodiments of the inventive concept. FIG. 1B is an enlarged view of a pattern and an anti-contamination layer of FIG. 1A.

Referring to FIGS. 1A and 1B, a photomask 50 according to some embodiments includes a substrate 100, patterns 110 on the substrate 100, and an anti-contamination layer 120 disposed on the patterns 110. The anticontamination layer may be disposed directly on the patterns, that is, having no intervening elements in between.

The anti-contamination layer 120 includes at least one graphene layer 125. The anti-contamination layer 120 is in contact with at least top surfaces of the patterns 110.

The graphene layer 125 may include carbon atoms that have a nano-sized structure and are two-dimensionally arranged. Thus, the graphene layer 125 is chemically and/or structurally stable. Thus, the graphene layer 125 does not substantially react with external contamination materials such as fine dust and/or particles. As a result, the external contamination materials are less likely to adhere to the graphene layer 125. Additionally, the graphene layer 125 has an improved light transmittance with respect to light used in a photolithography process. As a result, the external contamination materials are less likely to adhere to the anti-contamination layer 120 including the graphene layer 125, so that a cleaning period and a lifetime of the photomask 50 may increase. Additionally, since the anti-contamination layer 120 may be disposed directly on the patterns 110, the external contamination material may not occur on the patterns 110. Moreover, since the graphene layer 125 has an improved light transmittance, optical loss caused at least by the anti-contamination layer 120 may be minimized in the photolithography process using the photomask 50. That is, the anti-contamination layer 120 may not influence the photolithography process. The anti-contamination layer 120 including the graphene layer 125 may function as a repellent layer. The light transmittance of the anti-contamination layer 120 will be described in more detail later.

According to some embodiments, the anti-contamination layer 120 may be in contact with the top surfaces of the patterns 110 but may be spaced apart from the substrate 100 between the patterns 110. In more detail, the anti-contamination layer 120 may include a first portion contacting the top surface of each pattern 110 and a second portion disposed over the substrate 100 between the patterns 110. In this case, the second portion of the anti-contamination layer 120 may be spaced apart from the substrate 100 and the patterns 110. The anti-contamination layer 120 may be substantially flat. Alternatively, the second portion of the anti-contamination layer 120 may be lower than the first portion of the anti-contamination layer 120. That is, a distance between the substrate 100 and the second portion of the anti-contamination layer 120 may be less than a distance between the substrate 100 and the first portion of the anti-contamination layer 120.

In some embodiments, the graphene layer 125 of the anti-contamination layer 120 may be in contact with the top surfaces of the patterns 110.

In some embodiments, the anti-contamination layer 120 may include a plurality of sequentially stacked graphene layers 125, as illustrated in FIG. 1B. A lowermost one of the graphene layers 125 may be in contact with the top surfaces of the patterns 110 and may be spaced apart from the substrate 100 between the patterns 110. For example, each of the graphene layers 125 may have a thickness of about 0.34 nm and a density of about 2.15 g/cm³. However, the inventive concept is not limited thereto.

As described above, since the graphene layers 125 are chemically and/or structurally stable, the external contamination material may not adhere to the anti-contamination layer 120. If the external contamination material occurs on the anti-contamination layer 120, an uppermost one of the stacked graphene layers 125 may be more readily removed using oxygen-plasma. Thus, the external contamination material on the anti-contamination layer 120 may be more readily removed without damage and/or distortion of the photomask 50. Additionally, the anti-contamination layer 120 still includes the graphene layers 125 under the uppermost graphene layer, so that the photomask 50 may be used without cleaning of the photomask 50. Thus, productivity of a semiconductor device may be improved.

In other embodiments, the anti-contamination layer 120 may include a single graphene layer 125.

The graphene layer 125 may be doped with impurities. For example, the impurities may include at least one of boron, nitrogen, fluorine, platinum, gold, silver, and kalium. However, the inventive concept is not limited thereto. The impurities may include at least one of other elements.

Since the graphene layer 125 may be doped with at least one impurity, various properties of the graphene layer 125 may be controlled. For example, if the graphene layer 125 is doped with boron (B) and/or nitrogen (N), electric properties of the graphene layer 125 may be controlled or changed. If the graphene layer 125 is doped with fluorine (F), chemical stability of the graphene layer 125 may be improved. For example, fluorine atoms may be combined with end-points of covalent bonds and/or defect sites in the graphene layer 125. Thus, the chemical stability of the graphene layer 125 may be more improved.

In some embodiments, the photomask 50 may be a transmission type photomask. In this case, the substrate 100 may be formed of a material transmitting light, and the patterns 110 may be formed of a material blocking light. For example, the substrate 100 may be formed of quartz, and the patterns 110 may be formed of chromium (Cr). Alternatively, the substrate 100 may be formed of another material transmitting light, and the patterns 110 may be formed of another material blocking light. In the photolithography process, light is blocked by the patterns 110 but light passes through the substrate 100 between the patterns 110. Thus, the patterns 110 of the photomask 50 may be projected on a photoresist layer formed on a semiconductor substrate. If the photomask 50 is the transmission type photomask, the light of the photolithography process may be a g-line laser having a wavelength of about 436 nm, an i-line laser having a wavelength of about 365 nm, a krypton fluoride (KrF) laser having a wavelength of about 248 nm, an argon fluoride (ArF) laser having a wavelength of about 193 nm, a fluorine (F₂) laser having a wavelength of about 157 nm, or a deep ultraviolet (DUV), for example, around 200 nm.

In other embodiments, the photomask 50 may be a reflection type photomask. In this case, the substrate 100 may include a material or structure reflecting light, and the patterns 110 may include a material absorbing light. For example, the substrate 100 may have a multi-layered structure including silicon (Si) layers and molybdenum (Mo) layers that are alternately and repeatedly stacked. The patterns 110 may include tantalum nitride. However, the inventive concept is not limited thereto. The substrate 100 may have another material or structure reflecting light, and the patterns 110 may include another material absorbing light. If the photomask 50 is the reflection type photomask, the light of the photolithography process may be extreme ultraviolet (EUV).

If the photomask is the transmission type photomask, the anti-contamination layer 120 may have a one-pass transmittance. The one-pass transmittance of the anti-contamination layer 120 is defined as a ratio of an intensity of light passing through the anti-contamination layer 120 once to an intensity of incident light. The one-pass transmittance of the anti-contamination layer 120 is expressed as a percentage (%). For example, the one-pass transmittance of the anti-contamination layer 120 may be equal to or greater than about 80%. In particular, the one-pass transmittance of the anti-contamination layer 120 may be equal to or greater than about 90%.

If the photomask is the reflection type photomask, the anti-contamination layer 120 may have a two-pass transmittance. The two-pass transmittance of the anti-contamination layer 120 is defined as a ratio of an intensity of light passing through the anti-contamination layer 120 twice to the intensity of the incident light. The two-pass transmittance of the anti-contamination layer 120 is expressed as a percentage (%). In more detail, if the photomask is the reflection type photomask, after the incident light passes through the anti-contamination layer 120, the light is reflected by the substrate 100 and then passes through the anti-contamination layer 120 again. The light passing through anti-contamination layer 120 again is irradiated to the photoresist layer formed on the semiconductor substrate. Thus, the two-pass transmittance of the photomask 50 is a relevant factor in the case where the photomask 50 is the reflection type photomask. For example, if the photomask 50 is the reflection type photomask, the two-pass transmittance of the anti-contamination layer 120 may be equal to or greater than about 80%. In particular, the two-pass transmittance of the anti-contamination layer 120 may be equal to or greater than about 90%.

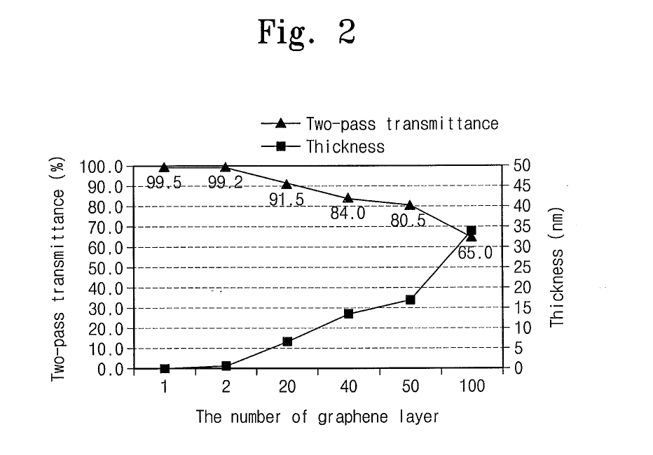

A simulation was performed in order to confirm the transmittance of the anti-contamination layer 120. This will be described in more detail with reference to FIG. 2.

FIG. 2 is a graph illustrating a transmittance property of an anti-contamination layer according to embodiments of the inventive concept. In the present simulation, an EUV having a wavelength of 13.5 nm was used as a light source and the photomask 50 was a reflection type photomask. In FIG. 2, an x-axis shows the number of stacked graphene layers 125 in the anti-contamination layer 120, a left y-axis shows the two-pass transmittance, and a right y-axis shows a thickness of the anti-contamination layer 120.

Referring to FIGS. 1A, 1B, and 2, if the anti-contamination layer 120 consists of a single graphene layer 125, the two-pass transmittance of the anti-contamination layer 120 is about 99.5%. If the number of the stacked graphene layers 125 is 50, the two-pass transmittance of the anti-contamination layer 120 is about 80.5%. If the number of the stacked graphene layers 125 is 20, the two-pass transmittance of the anti-contamination layer 120 is about 91.5%. Thus, if the photomask 50 is a reflection type photomask, and the light source is EUV, the number of graphene layers 125 in the anti-contamination layer 120 may have a range of 1 to about 50. In particular, the number of graphene layers 125 in the anti-contamination layer 120 may have a range of 1 to about 20.

Meanwhile, the one-pass transmittance of the anti-contamination layer 120 may be predicted from the graph of FIG. 2. For example, the one-pass transmittance of the single graphene layer 125 may be greater than about 99.5%. If the number of the stacked graphene layers 125 is 40, the one-pass transmittance of the anti-contamination layer 120 may be about 91.5%. If the number of the stacked graphene layers 125 is 100, the one-pass transmittance of the anti-contamination layer 120 may be about 80.5%. Thus, if the photomask 50 is the transmission type photomask and the light source is EUV, the number of the graphene layer 125 in the anti-contamination layer 120 may have a range of 1 to about 100 and, more particularly, a range of 1 to about 40.

An additional experiment was performed in order to confirm the transmittance of the graphene layer 125 of the anti-contamination layer 120. As a result, the transmittance of the single graphene layer 125 with respect to white light was about 97.7%.

As described above, the photomask 50 has the anti-contamination layer 120 including at least one graphene layer 125. Thus, the external contamination materials rarely adhere to the anti-contamination layer 120, so that the cleaning period and the lifetime of the photomask 50 may increase. Additionally, since the anti-contamination layer 120 is disposed directly on the patterns 110, the external contamination materials may be prevented from directly adhering to the patterns 110. Thus, the lifetime of the photomask 50 may further increase. Moreover, since the graphene layer 125 of the anti-contamination layer 120 has a desirable light transmittance, the anti-contamination layer 120 rarely influences the photolithography process using the photomask 50.

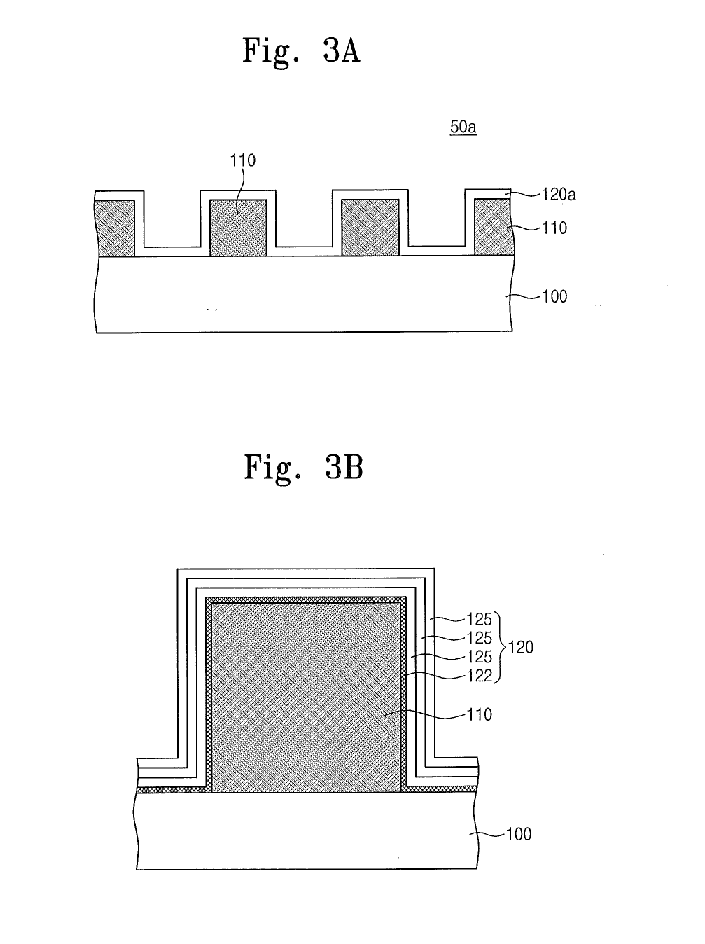

FIG. 3A is a cross-sectional view illustrating a photomask according to other embodiments of the inventive concept. FIG. 3B is an enlarged view of a pattern and an anti-contamination layer of FIG. 3A.

Referring to FIGS. 3A and 3B, a photomask 50a according to the present embodiment may include an anti-contamination layer 120a conformally disposed on the substrate 100 having the patterns 110. In more detail, the anti-contamination layer 120a may conformally extend along surfaces (i.e., top surfaces and sidewalls) of the patterns 110 and a surface of the substrate 100 between the patterns 110. The anti-contamination layer 120a may have a substantially uniform thickness. The anti-contamination layer 120a may be in contact with the surfaces of the patterns 110 and the surface of the substrate 100 between the patterns 110.

As illustrated in FIG. 3B, the anti-contamination layer 120a according to the present embodiment may include a seed layer 122 and at least one graphene layer 125 stacked on the seed layer 122. The seed layer 122 may be in contact with the surfaces of the patterns 110 and the surface of the substrate 100 between the patterns 110, and the graphene layer 125 may be in contact with a top surface of the seed layer 122. The anti-contamination layer 120a may include a single graphene layer 125 or a plurality of sequentially stacked graphene layers 125.

The seed layer 122 may include a transition metal. For example, the seed layer 122 may include at least one of copper (Cu) and nickel (Ni). However, the inventive concept is not limited thereto. In other embodiments, the seed layer 122 may be any substrate (e.g., SiC) containing a very small amount of carbon or may include at least one of other transition metal. The seed layer 122 may have a thickness which rarely influences a one-pass transmittance or a two-pass transmittance of the anti-contamination layer 120a. For example, the seed layer 122 may have the thickness of several angstroms to several tens of angstroms.

The photomask 50a may be a reflection type photomask or a transmission type photomask, as described with reference to FIGS. 1A and 1B. The anti-contamination layer 120a including the seed layer 122 and the at least one graphene layer 125 may have a one-pass transmittance of about 80% or more, or a two-pass transmittance of about 80% or more. In particular, the anti-contamination layer 120a may have a one-pass transmittance of about 90% or more, or a two-pass transmittance of about 90% or more.

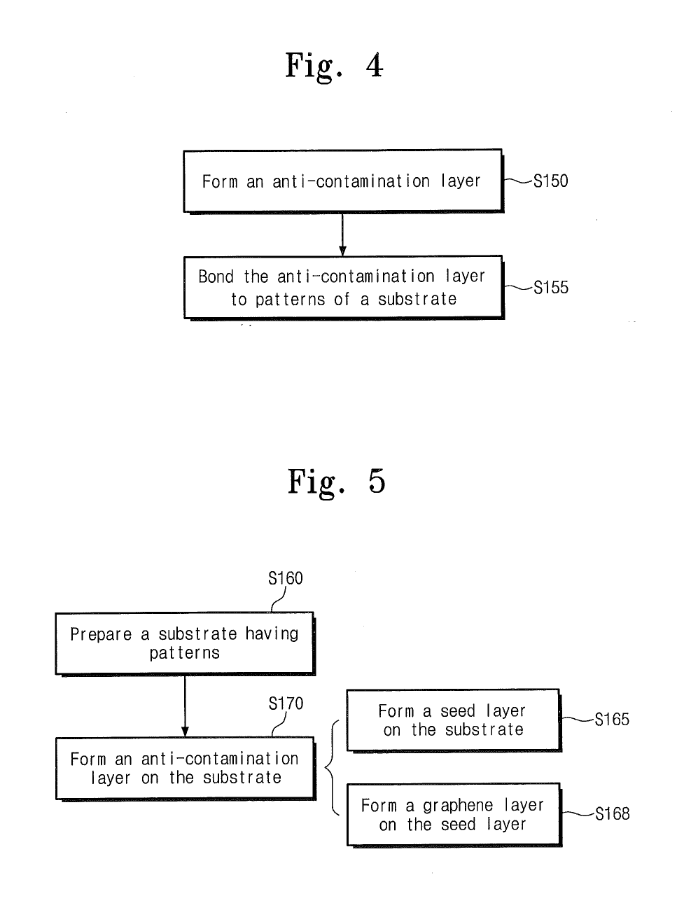

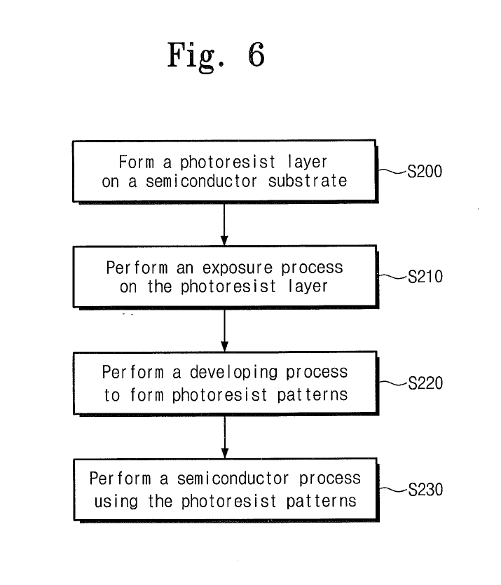

Next, methods of forming the photomasks 50 and 50a will be described with reference to FIGS. 4 and 5.

FIG. 4 is a flowchart illustrating a method of forming a photomask according to some embodiments of the inventive concept.

Referring to FIGS. 1A, 1B, and 4, an anti-contamination layer 120 is formed (S150). The anti-contamination layer 120 may be formed to have a single graphene layer 125 or a plurality of stacked graphene layers 125. In some embodiments, the anti-contamination layer 120 including the graphene 125 may be formed on a seed substrate including a transition metal by a thermal chemical vapor deposition (TCVD) process and/or a plasma-enhanced chemical vapor deposition (PE-CVD) process. The anti-contamination layer 120 may be separated from the seed substrate. However, the inventive concept is not limited thereto. The anti-contamination layer 120 may be formed by various other methods.

The substrate 100 having the patterns 110 is prepared. The anti-contamination layer 120 may be bonded to the patterns 110 of the substrate 100 (S155). For example, the substrate 100 having the patterns 110 may be immersed within a solution (e.g., deionized water) in a bath. The anti-contamination layer 120 may be floated on the solution. The substrate 100 may be raised to bond the anti-contamination layer 120 to the top surfaces of the patterns 110. Subsequently, the substrate 100 may be dried using heat. Thus, the photomask 50 of FIGS. 1A and 1B may be realized. However, the inventive concept is not limited thereto. In other embodiments, the anti-contamination layer 120 may be bonded to the patterns 110 of the substrate 100 by another method such as a thermal release tape transfer method.

FIG. 5 is a flowchart illustrating a method of forming a photomask according to other embodiments of the inventive concept.

Referring to FIGS. 3A, 3B, and 5, the substrate 100 having the patterns 110 is prepared (S160). An anti-contamination layer 120a may be formed on the substrate 100 (S170). The step S170 may include forming a seed layer (S165) and forming a graphene layer 125 (S168). In more detail, the seed layer 122 may be formed on the substrate 100 having the patterns 110 (S165). The seed layer 122 may be conformally formed on surfaces of the patterns 110 and a surface of the substrate 100 between the patterns 110. In some embodiments, the seed layer 122 may be in contact with the surfaces of the patterns 110 and the surface of the substrate 100 between the patterns 110.

The seed layer 122 may be formed by a physical vapor deposition (PVD) process, a chemical vapor deposition (CVD) process, and/or an atomic layer deposition (ALD) process. As described above, the seed layer 122 may include the transition metal.

The graphene layer 125 may be formed on the seed layer 122 (S168). The graphene layer 125 may be formed by a TCVD process or PE-CVD process using the seed layer 122 as a seed. Particularly, the graphene layer 125 may be formed by the PE-CVD process performed at a low process temperature. The anti-contamination layer 120a may include a single graphene layer 125 or a plurality of stacked graphene layers 125. Thus, the photomask 50a of FIGS. 3A and 3B may be realized. However, the inventive concept is not limited thereto. The photomask 50a may be formed by another method.

Next, a method of fabricating a semiconductor device using the photomask 50 or 50a will be described with reference to the drawings.

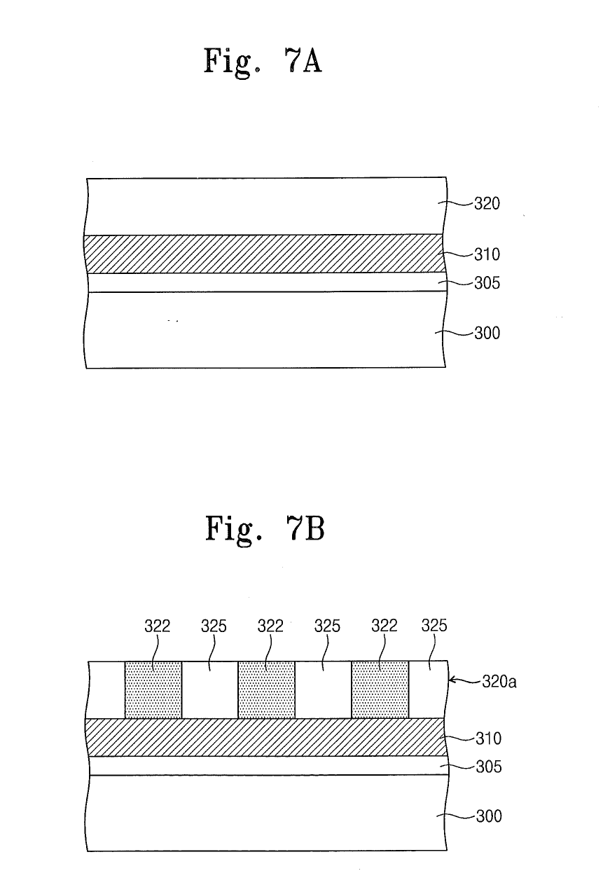

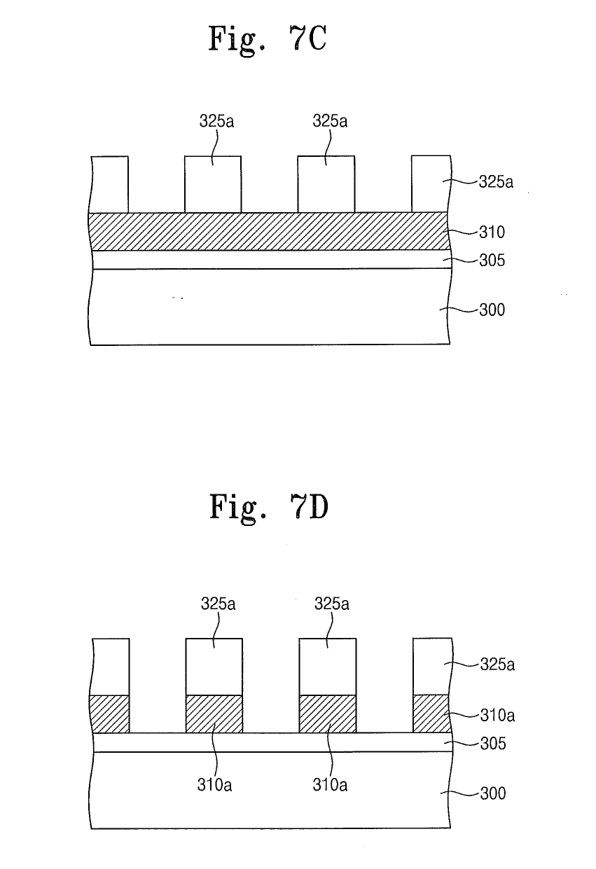

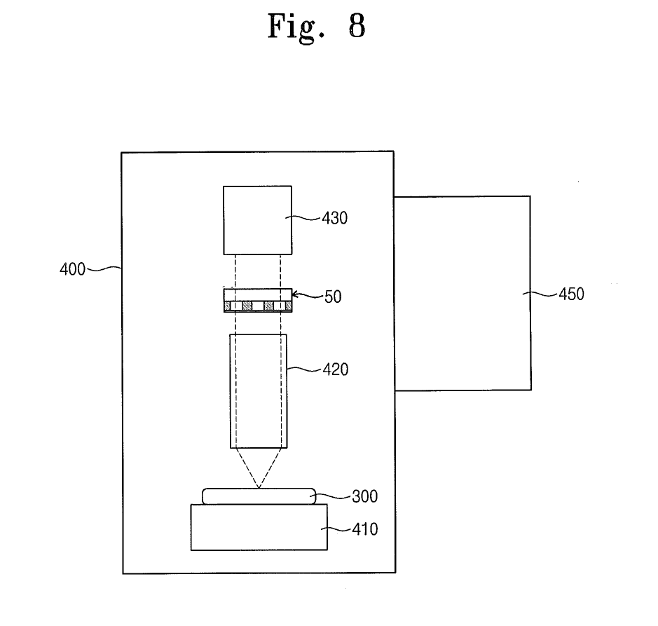

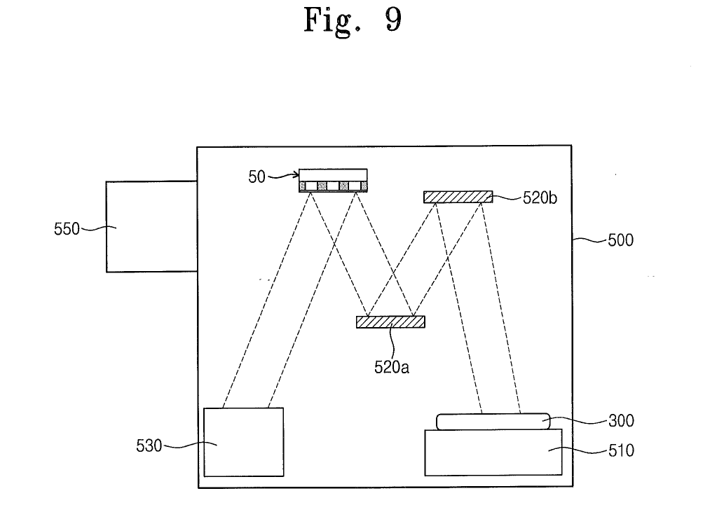

FIG. 6 is a flowchart illustrating a method of fabricating a semiconductor device according to example embodiments of the inventive concept. FIGS. 7A to 7D are cross-sectional views illustrating a method of fabricating a semiconductor device according to example embodiments of the inventive concept. FIG. 8 is a schematic diagram illustrating an exposure system to explain an exposure process according to some embodiments of the inventive concept. FIG. 9 is a schematic diagram illustrating an exposure system to explain an exposure process according to other embodiments of the inventive concept.

Referring to FIGS. 6 and 7A, a photoresist layer 320 is formed on a semiconductor substrate 300 for formation of a semiconductor device (S200). For example, the semiconductor substrate 300 may be a silicon substrate. A semiconductor process using the photoresist layer 320 may be one of various semiconductor processes. For example, the semiconductor process using the photoresist layer 320 may be an etching process or an ion implantation process. If the semiconductor process using the photoresist layer 320 is the etching process, an etch target layer 310 may be formed on the semiconductor substrate 300 and then the photoresist layer 320 may be formed on the etch target layer 310. If the etch target layer 310 is a conductive layer, an insulating layer 305 may be formed between the etch target layer 310 and the semiconductor substrate 300. Alternatively, the etch target layer 310 may be an insulating layer. In this case, a conductive pattern (not shown) may be formed under the etch target layer 310.

If the semiconductor process using the photoresist layer 320 is an ion implantation process, the etch target layer 310 may be omitted and the photoresist layer 320 may be formed on an ion implantation target region. The ion implantation target region may be a portion of the semiconductor substrate 300 or a semiconductor layer (e.g., a poly-silicon layer) disposed on the semiconductor substrate 300.

The photoresist layer 320 may be formed on the semiconductor substrate 300 by a spin coating process. After the photoresist layer 320 is coated on the semiconductor substrate 300, a soft bake process may be performed.

Referring to FIGS. 6 and 7B, an exposure process is performed on the photoresist layer 320 (S210). The exposure process is performed using the photomask 50 or 50a described above. If the photomask 50 or 50a is the transmission type photomask, the exposure process may be performed using a transmission type exposure system. FIG. 8 schematically illustrates the transmission type exposure system. The exposure process using the photomask 50 or 50a of the transmission type will be described in more detail with reference to FIG. 8.

Referring to FIGS. 7A and 8, the transmission type exposure system may include a housing 400. A stage 410, a lens system 420, and a light source 430 may be disposed within the housing 400. The photomask 50 may be installed on the lens system 420. In FIG. 8, the photomask 50 of FIGS. 1A and 1B is illustrated as an example. In other embodiments, the photomask 50 of FIG. 8 may be replaced with the photomask 50a of FIGS. 3A and 3B.

The semiconductor substrate 300 having the photoresist layer 320 may be loaded on the stage 410. Light generated from the light source 430 may sequentially pass through the photomask 50 and the lens system 420 and then may be irradiated to the photoresist layer 320 of the semiconductor substrate 300 loaded on the stage 410.

In some embodiments, the transmission exposure system may further include a photomask-cleaning unit 450 installed on a side of the housing 400. The photomask-cleaning unit 450 may generate oxygen-plasma. If the external contamination material occurs on the anti-contamination layer 120 of the photomask 50, the photomask 50 may be loaded in the photomask-cleaning unit 450 and then the oxygen-plasma may be generated to remove the graphene layer 125 of the anti-contamination layer 120. As a result, the external contamination material may be removed. Alternatively, the transmission type exposure system may not include the photomask-cleaning unit 450. In this case, the graphene layer 125 of the anti-contamination layer 120 may be removed by an additional cleaning apparatus.

On the other hand, the photomask 50 or 50a may be the reflection type photomask. In this case, the exposure process may be performed using a reflection type exposure system. FIG. 9 schematically illustrates the reflection type exposure system. The exposure process using the photomask 50 or 50a of the reflection type will be described in more detail with reference to FIG. 9.

Referring to FIGS. 7A and 9, in some embodiments, the reflection type exposure system includes a stage 510, a light source 530 and reflectors 520a and 520b which are installed in a housing 500. The photomask 50 may be installed in the housing 500, and the semiconductor substrate 300 having the photoresist layer 320 may be loaded on the stage 510.

Light generated from the light source 530 may be reflected by the photomask 50 and the reflectors 520a and 520b and then may be irradiated to the photoresist layer 320 of the semiconductor substrate 300.

The reflection exposure system may further include a photomask-cleaning unit 550 installed on a side of the housing 500. The photomask-cleaning unit 550 may generate the oxygen-plasma.

Referring again to FIG. 7B, the exposed photoresist layer 320a may include exposed portions 322 and unexposed portions 325 by the patterns 110 of the photomask 50 or 50a.

Referring to FIGS. 6 and 7C, a developing process may be performed on the exposed photoresist layer 320a to form photoresist patterns 325a (S220). Due to the developing process, the exposed portions 322 may be removed and the unexposed portions 325 may remain. The remaining unexposed portions 325 may correspond to the photoresist patterns 325a. In some embodiments, a hard bake process may be performed on the remaining unexposed portions 325 to form the photoresist patterns 325a. The developing process may use a developing solution.

In other embodiments, if the photoresist layer 320 is a negative photoresist layer, the unexposed portions 325 may be removed and the exposed portions 322 may remain by the developing process.

Referring to FIG. 7D, the semiconductor process is performed using the photoresist patterns 325a (S230). As described above, the semiconductor process may be one of various processes. For example, the semiconductor process may be the etching process or the ion implantation process. If the semiconductor process is the etching process, the etch target layer 310 may be etched using the photoresist patterns 325a as etch masks, thereby forming semiconductor patterns 310a. If the etch target layer 310 is the conductive layer, the semiconductor patterns 310a may include interconnections, gate lines, and/or pad patterns. Alternatively, if the etch target layer 310 is the insulating layer, holes and/or grooves may be formed in the etch target layer 310 by the etching process, or insulating patterns may be formed by the etching process.

If the semiconductor process is the ion implantation process, the ion implantation process may be performed using the photoresist patterns 325a as ion implantation masks.

After the semiconductor process is performed, the photoresist patterns 325a may be removed.

As described above, the semiconductor devices formed using the photomask 50 or 50a may be realized as a dynamic random access memory (DRAM) device, a static random access memory (SRAM) device, a two-dimensional flash memory device, a three-dimensional flash memory device, a magnetic memory device, a phase change memory device, a ferroelectric RAM device, a read only memory (ROM) device, a logic device, a controller, or a system on chip (SoC).

The semiconductor devices formed using the photomask according to the aforementioned embodiments may be encapsulated using various packaging techniques. For example, the semiconductor devices may be encapsulated using any one of a package on package (POP) technique, ball grid arrays (BGAs) technique, chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique and a wafer-level processed stack package (WSP) technique.

The semiconductor devices formed using the photomask according to the aforementioned embodiments may be applied to electronic systems such as a computer system, a memory card, a mobile phone, a smart pad, and/or a smart phone.

According to embodiments of the inventive concept, the anti-contamination layer including the graphene layer is disposed directly on the patterns. The graphene layer is chemically and/or structurally stable. Thus, the external contamination material rarely sticks to the anti-contamination layer. As a result, the cleaning period and/or the lifetime of the photomask may increase. Additionally, since the anti-contamination layer is disposed directly on the patterns of the photomask, the external contamination material may be prevented from directly adhering to the patterns. Thus, the lifetime of the photomask may further increase. Moreover, since the graphene layer of the anti-contamination layer possesses favorable light transmittance, the anti-contamination layer may not significantly influence the photolithography process using the photomask.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A photomask comprising:
a substrate;
patterns disposed on the substrate; and
an anti-contamination layer disposed on the patterns, the anti-contamination layer including at least one graphene layer.

2. The photomask of claim 1, wherein the anti-contamination layer is in contact with top surfaces of the patterns; and
wherein the anti-contamination layer is spaced apart from the substrate between the patterns.

3. The photomask of claim 2, wherein the graphene layer of the anti-contamination layer is in contact with the top surfaces of the patterns.

4. The photomask of claim 1, wherein the anti-contamination layer is in contact with surfaces of the patterns and a surface of the substrate between the patterns.

5. The photomask of claim 1, wherein the anti-contamination layer includes a first portion contacting a top surface of each pattern and a second portion disposed over the substrate between the patterns, wherein the second portion of the anti-contamination layer is spaced apart from the substrate and the patterns.

6. The photomask of claim 5, wherein a distance between the substrate and the second portion of the anti-contamination layer is less than a distance between the substrate and the first portion of the anti-contamination layer.

7. The photomask of claim 4, wherein the anti-contamination layer further comprises: a seed layer contacting the surfaces of the patterns and the surface of the substrate between the patterns; and
wherein the graphene layer is disposed on the seed layer and is in contact with the seed layer.

8. The photomask of claim 7, wherein the seed layer includes a transition metal.

9. The photomask of claim 1, wherein the anti-contamination layer includes a plurality of sequentially stacked graphene layers.

10. The photomask of claim 1, wherein the graphene layer is doped with impurities.

11. The photomask of claim 10, wherein the impurities include at least one of boron, nitrogen, fluorine, platinum, gold, silver, and kalium.

12. The photomask of claim 1, wherein the substrate includes a material transmitting light generated from a light source; and
wherein the patterns include a material blocking the light.

13. The photomask of claim 1, wherein the anti-contamination layer has a one-pass transmittance equal to or greater than about 80%.

14. The photomask of claim 1, wherein the substrate includes a material or structure reflecting light generated from a light source; and
wherein the patterns include a material absorbing the light.

15. The photomask of claim 1, wherein the anti-contamination layer has a two-pass transmittance equal to or greater than about 80%.

16.-20. (canceled)
